(19) United States
(12) Patent Application Publication
(10) Pub. No.: US 2025/0254866 A1
(43) Pub. Date: Aug. 7, 2025

(54) SEMICONDUCTOR MEMORY DEVICE

(71) Applicant: Samsung Electronics Co., Ltd., Suwon-si (KR)

(72) Inventors: CHEONBAE KIM, Suwon-si (KR); BYUNGHOON CHO, Suwon-si (KR); ILJAE SHIN, Suwon-si (KR)

(21) Appl. No.: 18/794,568

(22) Filed: Aug. 5, 2024

(30) Foreign Application Priority Data
Feb. 1, 2024 (KR) 10-2024-0016138

(51) Int. Cl. H10B 12/00

(52) U.S. Cl. CPC H10B 12/50; H10B 12/315; H10B 12/482; H10B 12/488

(57) ABSTRACT

Disclosed is a semiconductor memory device comprising a substrate that includes a first region, a boundary region, and a second region that are linearly disposed in a first direction, and a peripheral structure and a cell structure that are sequentially stacked on the substrate. The cell structure includes a plurality of cell bottom electrodes on the first region and the second region, a plurality of dummy bottom electrodes on the boundary region, a top electrode that covers the cell bottom electrodes and the dummy bottom electrodes, and a dielectric layer between the top electrode and the cell bottom electrodes and between the top electrode and the dummy bottom electrodes.

### CROSS-REFERENCE TO RELATED APPLICATION

This U.S. nonprovisional application claims priority under 35 U.S.C. § 119 to Korean Patent Application No. 10-2024-0016138, filed on Feb. 1, 2024, in the Korean Intellectual Property Office, the disclosure of which is hereby incorporated by reference in its entirety.

### BACKGROUND

The present inventive concepts relate to a semiconductor memory device, and more particularly, to a semiconductor memory device including dummy lower electrodes.

Semiconductor devices have been highly integrated to meet high performance and low manufacturing cost which are required by customers. Because integration of the semiconductor devices is an important factor in determining product price, high integration is increasingly requested. Integration of typical two-dimensional or planar semiconductor devices is primarily determined by the area occupied by a unit memory cell, such that it is greatly influenced by the level of technology for forming fine patterns. However, the extremely expensive processing equipment needed to increase pattern fineness may set a practical limitation on increasing the integration of the two-dimensional or planar semiconductor devices. Accordingly, there have been suggested semiconductor memory devices to increase integration, resistance, and current driving capability of semiconductor apparatus.

### SUMMARY

Some embodiments of the present inventive concepts provide a semiconductor memory device with improved structural stability and increased integration.

The object of the present inventive concepts is not limited to the mentioned above, and other objects which have not been mentioned above will be clearly understood to those skilled in the art from the following description.

According to some embodiments of the present inventive concepts, a semiconductor memory device may comprise: a substrate that includes a first region, a boundary region, and a second region that are linearly disposed in a first direction; and a peripheral structure and a cell structure that are sequentially stacked on the substrate. The cell structure may include: a plurality of cell bottom electrodes on the first region and the second region; a plurality of dummy bottom electrodes on the boundary region; a top electrode that covers the cell bottom electrodes and the dummy bottom electrodes; and a dielectric layer between the top electrode and the cell bottom electrodes and between the top electrode and the dummy bottom electrodes.

According to some embodiments of the present inventive concepts, a semiconductor memory device may comprise: a substrate that includes a first region, a boundary region, and a second region that are linearly disposed in a first direction; and a peripheral structure and a cell structure that are sequentially stacked on the substrate. The peripheral structure may include: a plurality of peripheral transistors on the substrate; a first peripheral dielectric layer that covers the substrate; and a plurality of first peripheral lines in the first peripheral dielectric layer. The cell structure may include: a first cell dielectric layer and a second cell dielectric layer that sequentially cover the peripheral structure; a plurality of first cell lines in the first cell dielectric layer; a plurality of active patterns, a plurality of word lines, and a plurality of bit lines in the second cell dielectric layer; a plurality of cell bottom electrodes on the second cell dielectric layer on the first region and the second region; a plurality of dummy bottom electrodes on the second cell dielectric layer on the boundary region; a top electrode that covers the cell bottom electrodes and the dummy bottom electrodes; and a dielectric layer between the top electrode and the cell bottom electrodes and between the top electrode and the dummy bottom electrodes. The bit lines may connect bottom surfaces of the active patterns to each other and may extend in the first direction. The word lines may be adjacent to lateral surfaces of the active patterns and may extend in a second direction that intersects the first direction. An interval between the dummy bottom electrodes may be different from an interval between the cell bottom electrodes.

According to some embodiments of the present inventive concepts, a semiconductor memory device may comprise: a substrate that includes a first region, a boundary region, and a second region that are linearly disposed in a first direction; and a peripheral structure and a cell structure that are sequentially stacked on the substrate. The cell structure may include: a plurality of cell bottom electrodes on the first region and the second region; a plurality of dummy bottom electrodes on the boundary region; a top electrode that covers the cell bottom electrodes and the dummy bottom electrodes; a dummy landing pad that connects bottom surfaces of the dummy bottom electrodes to each other; and a dummy storage node contact beneath the dummy landing pad.

### BRIEF DESCRIPTION OF DRAWINGS

FIG. 1A illustrates a block diagram showing a semiconductor memory device according to some example embodiments of the present inventive concepts.

FIG. 1B illustrates a simplified perspective view showing a semiconductor memory device according to some example embodiments of the present inventive concepts.

FIG. 2 illustrates a simplified perspective view showing a semiconductor memory device according to some example embodiments of the present inventive concepts.

FIG. 3 illustrates a cross-sectional view taken along line A-A′ of FIG. 2.

FIG. 4 illustrates an enlarged view showing section P1 of FIG. 3.

FIG. 5 illustrates a plan view showing a cell array region according to some example embodiments of the present inventive concepts.

FIGS. 6, 7, and 8 illustrate cross-sectional views taken along line A-A′ of FIG. 2.

FIGS. 9A to 9G illustrate cross-sectional views showing an example method of fabricating the semiconductor memory device of FIG. 6.

### DETAILED DESCRIPTION OF EMBODIMENTS

Some embodiments of the present inventive concepts will now be described in detail with reference to the accompanying drawings to aid in clearly explaining the present inventive concepts. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

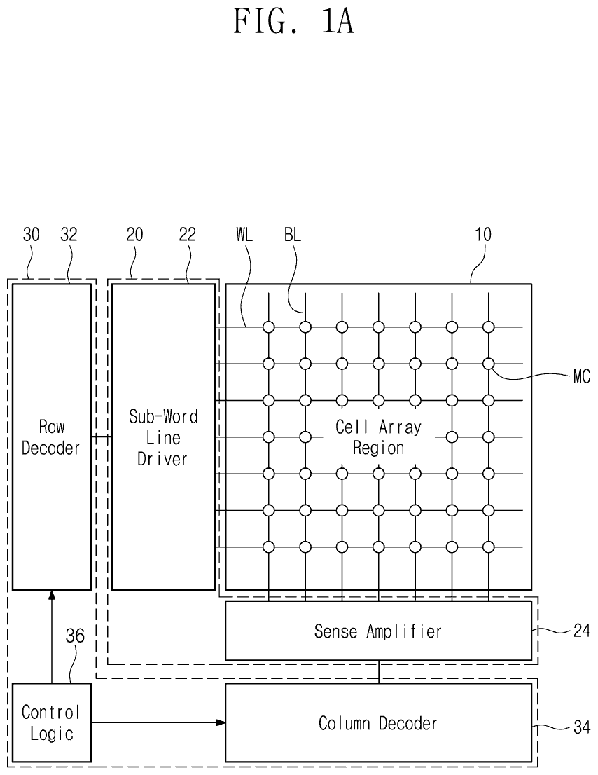

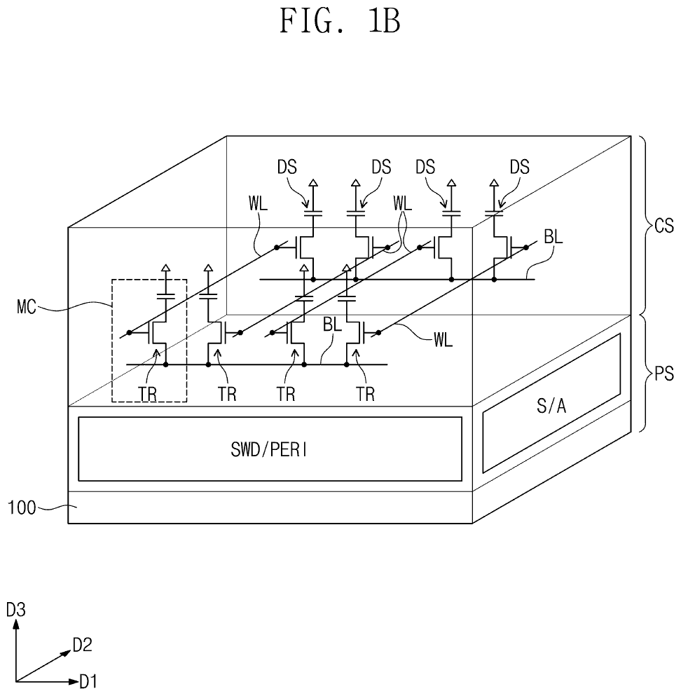

FIG. 1A illustrates a block diagram showing a semiconductor memory device according to some example embodiments of the present inventive concepts.

Referring to FIG. 1A, a semiconductor memory device according to the present embodiment may include a cell array region 10. The cell array region 10 may include word lines WL and bit lines BL that cross each other. A plurality of memory cells MC may be two-dimensionally or three-dimensionally disposed on the cell array region 10. Each of the memory cells MC may be connected between the word line WL and the bit line BL that cross each other.

A core region 20 may be disposed around the cell array region 10. The core region 20 may include a sub-word line driver 22 and a sense amplifier 24. A peripheral circuit region 30 may be disposed around the core region 20. A row decoder 32, a column decoder 34, and a control logic 36 may be disposed on the peripheral circuit region 30.

The row decoder 32 may decode a refresh address signal or a row address signal that is input from outside. In response to the row address signal or the refresh address signal, the sub-word line driver 22 may serve to select a specific word line WL.

In response to an address that is decoded from the column decoder 34, the sense amplifier 24 may detect and amplify a voltage difference between a selected bit line BL and a reference bit line, and may then output the amplified voltage difference.

The column decoder 34 may provide a data delivery path between the sense amplifier 24 and an external device (e.g., a memory controller). The column decoder 34 may decode an address that is input from outside and may select one of the bit lines BL.

The control logic 36 may generate control signals that control operations to write data to a memory cell array of the cell array region 10 and/or to read data from a memory cell array of the cell array region 10.

FIG. 1B illustrates a simplified perspective view showing a semiconductor memory device according to some example embodiments of the present inventive concepts.

Referring to FIG. 1B, a semiconductor memory device may include a substrate 100, a peripheral structure PS, and a cell structure CS. Unlike FIG. 1B, the cell structure CS may be positioned between the substrate 100 and the peripheral structure PS.

The peripheral structure PS may include a core region 20 and a peripheral circuit region 30 of FIG. 1A. The core region 20 may include sub-word line driver circuits SWD and sense amplifier circuits S/A. The peripheral circuit region 30 may include peripheral circuits PERI.

The cell structure CS may include a cell array region 10 of FIG. 1A. The cell structure CS may include bit lines BL, word lines WL, and memory cells MC between the bit lines BL and the word lines WL. The memory cells MC may be two-dimensionally or three-dimensionally arranged on a plane elongated in first and second directions D1 and D2 that intersect each other. Each of the memory cells MC may include a selection element TR and a data storage element DS.

The selection element TR may be a transistor. In one example embodiment, the selection element TR may be a field effect transistor (FET). A gate electrode of a transistor may be connected to the word line WL, and source/drain terminals of the transistor may be connected to the bit line BL and the data storage element DS. According to another example embodiment, a vertical channel transistor (VCT) may be included as the selection element TR of each memory cell MC. The vertical channel transistor may have a structure in which a channel length extends in a direction (or, a third direction D3) perpendicular to a top surface of the substrate 100.

The data storage element DS of each memory cell MC may include a capacitor, a magnetic tunnel junction pattern, or a variable resistor. In the present embodiment, a capacitor may be provided as the data storage element DS of each memory cell MC.

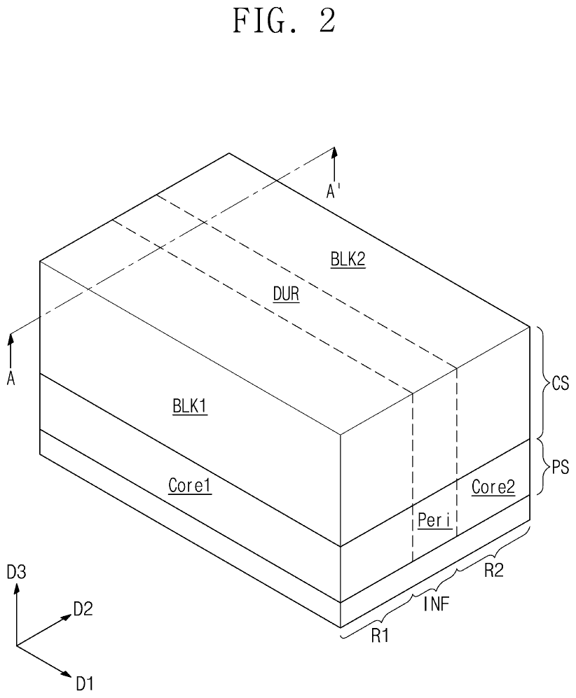

FIG. 2 illustrates a simplified perspective view showing a semiconductor memory device according to some example embodiments of the present inventive concepts.

Referring to FIG. 2, a semiconductor memory device may include a peripheral structure PS and a cell structure CS that are sequentially stacked on a substrate 100. The substrate 100 may include a first region R1, a boundary region INF, and a second region R2 that are linearly disposed in a second direction D2. For example, each of the first region R1, boundary region INF, and the second region R2 may extend lengthwise in a first direction D1, and the boundary region INF may be disposed between the first region R1 and the second region R2 in a second direction D2. The substrate 100 may be a silicon substrate, a silicon-on-insulator (SOI) substrate, or a dielectric substrate.

The peripheral structure PS may include first and second core regions Core1 and Core2 and a peripheral circuit region Peri that are two-dimensionally arrange along first and second directions D1 and D2. The first core region Core1 may be disposed on the first region R1. The second core region Core2 may be disposed on the second region R2.

In this description, the term “core region” may be called “core part.” The peripheral circuit region Peri may be positioned between the first core region Core1 and the second core region Core2, and may be disposed on the boundary region INF. In this description, the term “peripheral circuit region” may be called “peripheral circuit part.” In the present embodiment, two core regions are illustrated, but the number of core regions may be three or more without being limited to two. The arrangement of the first and second core regions Core1 and Core2 and the peripheral circuit region Peri may be variously changed without being limited to that shown in FIG. 2.

The cell structure CS may include first and second cell array regions BLK1 and BLK2 and a dummy region DUR that are two-dimensionally arranged along the first direction D1 and the second direction D2. In this description, the term “cell array region” may also be called “memory block.” The first cell array region BLK1 may be disposed on the first region R1. The second cell array region BLK2 may be disposed on the second region R2. The dummy region DUR may be positioned between the first cell array region BLK1 and the second cell array region BLK2, and may be disposed on the boundary region INF.

In the present embodiment, two cell array regions are illustrated, but the number of cell array regions may be three or more without being limited to two. The arrangement of the first and second cell array regions BLK1 and BLK2 and the dummy region DUR may be variously changed without being limited to that shown in FIG. 2.

The first and second cell array regions BLK1 and BLK2 may vertically overlap the first and second core regions Core1 and Core2, respectively. The first and second cell array regions BLK1 and BLK2 may be connected to the first and second core regions Core1 and Core2, respectively. For example, the first cell array regions BLK1 may be electrically connected to the first core region Core1 and the second cell array region BLK2 may be connected to the second core region Core2. The dummy region DUR may vertically overlap the peripheral circuit region Peri. The dummy region DUR may not be connected to the peripheral circuit region Peri.

Each of the first and second cell array regions BLK1 and BLK2 may correspond to the cell array region 10 of FIG. 1A. Each of the first and second cell array regions BLK1 and BLK2 may include the bit lines BL, the word lines WL and the memory cells MC discussed with reference to FIGS. 1A and 1B. Each of the first and second cell array regions BLK1 and BLK2 may include the sub-word line driver 22 and the sense amplifier 24 discussed with reference to FIG. 1A. The peripheral circuit region Peri may include the row decoders 32, the column decoders 34, and the control logics 36 discussed with reference to FIG. 1A.

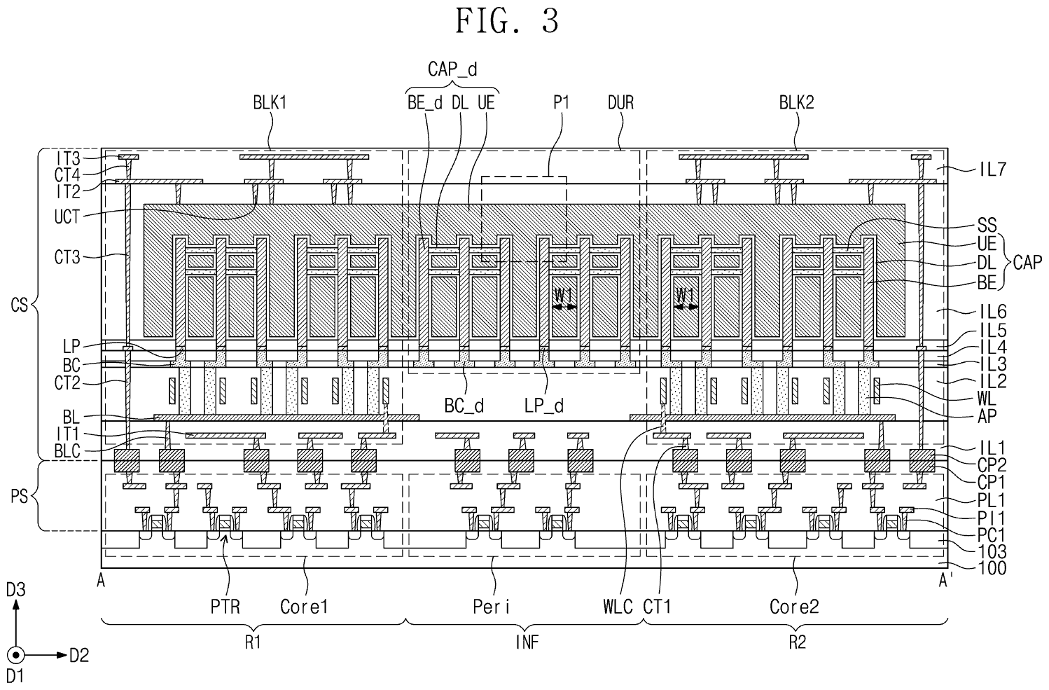

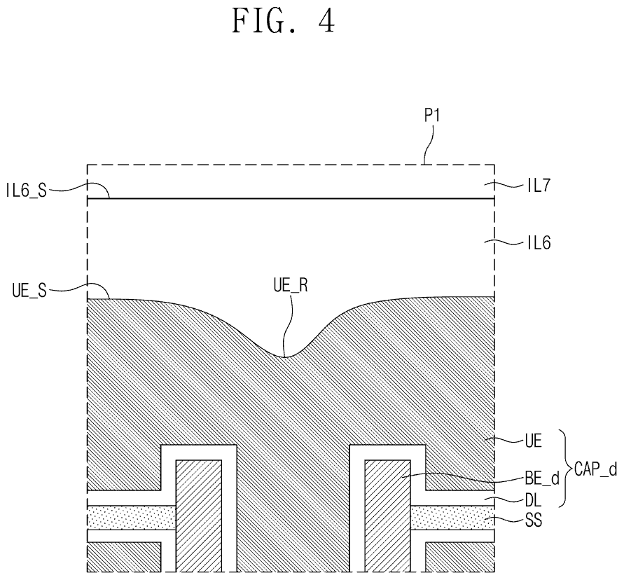

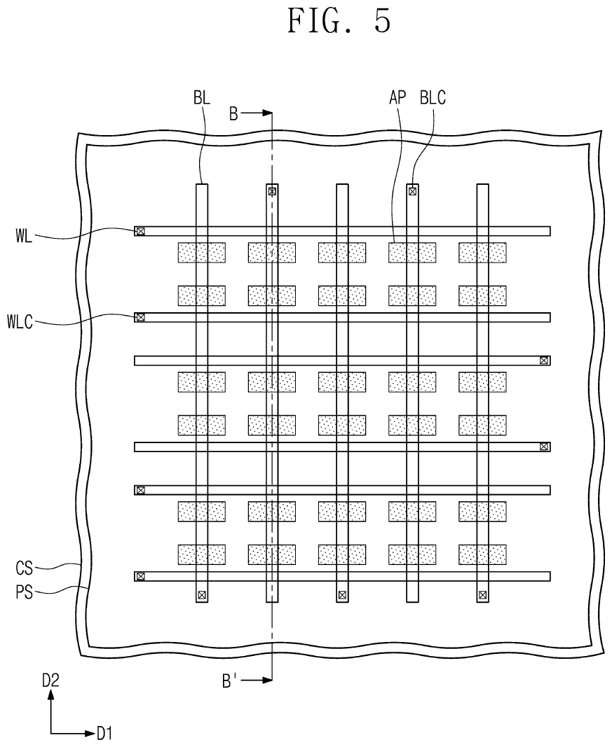

FIG. 3 illustrates a cross-sectional view taken along line A-A′ of FIG. 2. FIG. 4 illustrates an enlarged view showing section P1 of FIG. 3. FIG. 5 illustrates a plan view showing a cell array region according to some example embodiments of the present inventive concepts. The first and second cell array regions BLK1 and BLK2 of FIG. 3 may correspond to a cross-section taken along line B-B′ of FIG. 5.

Referring to FIGS. 2, 3, and 5, the peripheral structure PS and the cell structure CS that are sequentially stacked on the substrate 100. The substrate 100 may be provided therein with device isolation patterns 103 that define active sections for peripheral transistors PTR which will be discussed below. The device isolation patterns 103 may have a single-layered or multi-layered structure of at least one selected from silicon oxide and silicon nitride.

The peripheral structure PS may include peripheral transistors PTR, peripheral contact plugs PC1, peripheral lines PI1, and a peripheral dielectric layer PL1 that are disposed on the substrate 100. Each of the peripheral transistors PTR may be a planar transistor, a fin field effect transistor (FinFET), a multi-bridge channel FET (MBCFET), a gate all around (GAA) transistor, or a buried channel array transistor (BCAT). The peripheral transistors PTR may be connected to the peripheral contact plugs PC1 and the peripheral lines PI1. The peripheral dielectric layer PL1 may cover the peripheral transistors PTR, the peripheral contact plugs PC1, and the peripheral lines PI1. First connection pads CP1 may be disposed on upper ends of the peripheral dielectric layer PL1. The first connection pads CP1 may be connected to the peripheral contact plugs PC1 and the peripheral lines PI1.

The first connection pads CP1, the peripheral contact plugs PC1, and the peripheral lines PI1 each may be formed of or include metal, such as copper, aluminum, tungsten, titanium, tantalum, titanium nitride, or tantalum nitride. The peripheral dielectric layer PL1 may have a single-layered or multi-layered structure of at least one selected from silicon oxide, silicon nitride, silicon oxynitride, SiCN, and porous dielectrics.

Referring to FIGS. 1A and 3, in each of the first and second core regions Core1 and Core2, the peripheral transistors PTR, the peripheral contact plugs PC1, and the peripheral lines PI1, which components PC1 and PI1 are connected to the peripheral transistors PTR, may constitute the sense amplifiers 24 and the sub-word line drivers 22. The peripheral transistors PTR, the peripheral contact plugs PC1, and the peripheral lines PI1, of which the peripheral contact plugs PC1 and peripheral lines PI1 are connected to the peripheral transistors PTR, may be disposed on the peripheral circuit region Peri, and may constitute the row decoders 32, the column decoders 34, and the control logics 36.

Referring back to FIGS. 3 and 5, the cell structure CS may include first to seventh cell dielectric layers IL1 to IL7 that are sequentially stacked, and may also include bit lines BL, word lines WL, and capacitors CAP disposed in the first to seventh cell dielectric layers IL1 to IL7. Each of the first to seventh cell dielectric layers IL1 to IL7 may have a single-layered or multi-layered structure of at least one selected from silicon oxide, silicon nitride, silicon oxynitride, and porous dielectrics.

The first cell dielectric layer IL1 may be provided therein with first cell lines IT1 and first cell contact plugs CT1. The first cell dielectric layer IL1 may include second connection pads CP2 on a bottom end thereof, and the first connection pads CP1 may be correspondingly connected to the second connection pads CP2.

For example, in each of the first and second cell array regions BLK1 and BLK2, the bit lines BL may be disposed on the first cell dielectric layer IL1. The bit lines BL may extend in the second direction D2. The bit lines BL may be covered with the second cell dielectric layer IL2.

The bit lines BL may include, for example, conductive metal nitride (e.g., titanium nitride or tantalum nitride) or metal (e.g., tungsten, titanium or tantalum). The bit lines BL may include metal silicide, such as titanium silicide, cobalt silicide, or nickel silicide.

A bit-line contact plug BLC may penetrate the first cell dielectric layer IL1 to connect ends of the bit lines BL to the second connection pads CP2. A word-line contact plug WLC may penetrate a portion of the first cell dielectric layer IL1 and a portion of the second cell dielectric layer IL2 to connect an end of the word line WL to the first cell line IT1.

In each of the first and second cell array regions BLK1 and BLK2, active patterns AP may penetrate the second cell dielectric layer IL2 to come into contact with the bit lines BL. The bit lines BL may be connected to bottom surfaces of the active patterns AP. The word line WL may be disposed on one side of one of the active patterns AP. The word lines WL may extend lengthwise the first direction D1.

The word lines WL may include, for example, doped polysilicon, metal, conductive metal nitride, conductive metal silicide, conductive metal oxide, or any combination thereof. The active patterns AP may be formed of a single crystalline semiconductor material. For example, the active patterns AP may be formed of single crystalline silicon.

The third and fourth cell dielectric layers IL3 and IL4 may be sequentially disposed on the second cell dielectric layer IL2. In each of the first and second cell array regions BLK1 and BLK2, storage nodes contacts BC may penetrate the third and fourth cell dielectric layers IL3 and IL4 to come into contact with top ends of the active patterns AP.

Landing pads LP may be disposed on the storage node contacts BC. The landing pads LP may contact upper surfaces of the storage node contacts BC. The landing pads LP may completely or partially overlap the storage node contacts BC. When viewed in plan, the landing pads LP may be arranged in a matrix shape along the first direction D1 and the second direction D2. Alternatively, the landing pads LP may be arranged in a honeycomb shape when viewed in plan.

Cell bottom electrodes BE may be correspondingly disposed on the landing pads LP. The cell bottom electrodes BE may be electrically connected to corresponding active patterns AP. Each of the cell bottom electrodes BE may have a pillar shape or a hollow cup shape.

The cell bottom electrodes BE may be disposed in a honeycomb shape or a matrix shape along the first direction D1 and the second direction D2. The cell bottom electrodes BE may completely or partially overlap the landing pads LP. The cell bottom electrodes BE may be entirely or partially in contact with top surfaces of the landing pads LP. A constant interval may be provided between the cell bottom electrodes BE. The cell bottom electrodes BE may penetrate a portion of the fifth cell dielectric layer IL5 to come into contact with corresponding landing pads LP.

On the dummy region DUR, dummy storage node contacts BC_d may be disposed on the third and fourth cell dielectric layers IL3 and IL4. The dummy storage node contacts BC_d may be located at the same level as that of the storage node contacts BC. On the dummy region DUR, neither the active patterns AP nor the word lines WL may be disposed beneath the dummy storage node contacts BC_d.

The storage node contacts BC and the dummy storage node contacts BC_d may each have a width that is greater in the third cell dielectric layer IL3 than in the fourth cell dielectric layer IL4. The storage node contacts BC and the dummy storage node contacts BC_d may each have, when viewed in plan, a circular shape, an oval shape, a rectangular shape, a square shape, a rhombic shape, a hexagonal shape, or any other suitable shape. Each of the storage node contacts BC and the dummy storage node contacts BC_d may be arranged in a matrix shape along the first direction D1 and the second direction D2. The storage node contacts BC and the dummy storage node contacts BC_d may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or any combination thereof, but the present inventive concepts are not limited thereto.

On the dummy region DUR, dummy landing pads LP_d may be disposed on the dummy storage node contacts BC_d. The dummy landing pads LP_d may completely or partially vertically overlap the dummy storage node contacts BC_d. The dummy landing pads LP_d may contact upper surfaces of the dummy storage node contacts BC_d. When viewed in plan, the dummy landing pads LP_d may be arranged in a matrix shape along the first direction D1 and the second direction D2. Alternatively, the dummy landing pads LP_d may be arranged in a honeycomb shape when viewed in plan.

The landing pads LP and the dummy landing pads LP_d may each have, when viewed in plan, a circular shape, an oval shape, a rectangular shape, a square shape, a rhombic shape, a hexagonal shape, or any other suitable shape. The landing pads LP and the dummy landing pads LP_d may be formed of doped polysilicon, Al, Cu, Ti, Ta, Ru, W, Mo, Pt, Ni, Co, TiN, TaN, WN, NON, TiAl, TiAlN, TiSi, TiSiN, TaSi, TaSiN, RuTiN, NiSi, CoSi, IrOx, RuOx, or any combination thereof, but the present inventive concepts are not limited thereto.

Dummy bottom electrodes BE_d may be correspondingly disposed on the dummy landing pads LP_d. The dummy bottom electrodes BE_d may be disposed on the boundary region INF. Each of the dummy bottom electrodes BE_d may have a pillar shape or a hollow cup shape. The dummy bottom electrodes BE_d may be disposed in a honeycomb shape or a matrix shape along the first direction D1 and the second direction D2. The dummy bottom electrodes BE_d may completely or partially overlap the dummy landing pads LP_d. The dummy bottom electrodes BE_d may be entirely or partially in contact with top surfaces of the dummy landing pads LP_d. A constant interval may be provided between the dummy bottom electrodes BE_d. The dummy bottom electrodes BE_d may penetrate a portion of the fifth cell dielectric layer IL5 to come into contact with corresponding dummy landing pads LP_d.

As shown in FIG. 3, an interval between the cell bottom electrodes BE and an interval between the dummy bottom electrodes BE_d may have the same first width W1 in the second direction D2. Differently from that shown, the number of the cell bottom electrodes BE on the first cell array region BLK1 or the second cell array region BLK2 may be different from that of the dummy bottom electrodes BE_d on the boundary region INF. The cell bottom electrodes BE and the dummy bottom electrodes BE_d may include at least one selected from impurity-doped polysilicon, metal, metal oxide, and metal nitride. The cell bottom electrodes BE and the dummy bottom electrodes BE_d may include, for example, a titanium nitride layer.

The cell bottom electrodes BE and the dummy bottom electrodes BE_d may have their upper sidewalls that are in partial contact with support patterns SS. The support patterns SS may prevent collapse of the cell bottom electrodes BE and the dummy bottom electrodes BE_d. When viewed in plan, the support patterns SS may have a plate or mesh shape having a plurality of perforations formed therein. The support patterns SS may be formed into a single-layered structure or a multi-layered structure of two or more layers. The support patterns SS may be formed of a single or multiple layer of at least one selected from, for example, a silicon nitride (SiN) layer, a silicon boronitride (SiBN) layer, and a silicon carbonitride (SiCN) layer.

A dielectric layer DL may conformally cover the cell bottom electrodes BE, the dummy bottom electrodes BE_d, and the support patterns SS. The dielectric layer DL may cover a top surface of the fifth cell dielectric layer IL5. The dielectric layer DL may be formed of a single or multiple layer of at least one selected from, for example, a silicon oxide layer or a metal oxide layer such as an aluminum oxide layer having a material whose dielectric constant is greater than that of a silicon oxide layer.

A top electrode UE may be disposed on the dielectric layer DL. The top electrode UE may cover the cell bottom electrodes BE and the dummy bottom electrodes BE_d. The top electrode UE may fill spaces between the cell bottom electrodes BE and the dummy bottom electrodes BE_d. The top electrode UE may be formed of a single or multiple layer of at least one selected from a titanium nitride layer, a tungsten layer, an impurity-doped polysilicon layer, and an impurity-doped silicon-germanium layer.

In the present inventive concepts, the top electrode UE may cover all of the first region R1, the second region R2, and the boundary region INF. The top electrode UE may not be cut between the boundary region INF and the first and second regions R1 and R2. Thus, no misalignment margin may be required for cutting the top electrode UE. Therefore, there may be a reduction in interval between the first and second cell array regions BLK1 and BLK2, in size of a semiconductor memory device, and in signal delivery distance. Accordingly, the semiconductor memory device may increase in integration. In addition, a delamination may be prevented between the top electrode UE and the fifth cell dielectric layer IL5. As a result, the semiconductor memory device may improve in structural stability.

The cell bottom electrodes BE, the dielectric layer DL, and the top electrode UE may constitute the capacitors CAP. The capacitors CAP may correspond to the data storage element DS of FIG. 1B. The dummy bottom electrodes BE_d, the dielectric layer DL, and the top electrode UE may constitute dummy capacitors CAP_d. The dummy capacitors CAP_d may not be connected to the word lines WL or the bit lines BL. The capacitors CAP, the dummy capacitors CAP_d, and the fifth cell dielectric layer IL5 may be covered with the sixth cell dielectric layer IL6. The seventh cell dielectric layers IL7 may be disposed on the sixth cell dielectric layer IL6.

Second and third cell contact plugs CT2 and CT3 may penetrate at least one of the first to sixth cell dielectric layers IL1 to IL6 to connect second cell lines IT2 to the second connection pads CP2. An upper electrode contact plug UCT may penetrate the sixth cell dielectric layer IL6 to come into contact with a top surface of the top electrode UE. Fourth cell contact plugs CT4 may penetrate at least a portion of the seventh cell dielectric layer IL7 to connect third cell lines IT3 to the second cell lines IT2.

Referring to FIGS. 3 and 4, a top surface UE_S of the top electrode UE may have a recess UE_R on the boundary region INF. On the recess UE_R, the sixth cell dielectric layer IL6 may have a flat top surface IL6_S.

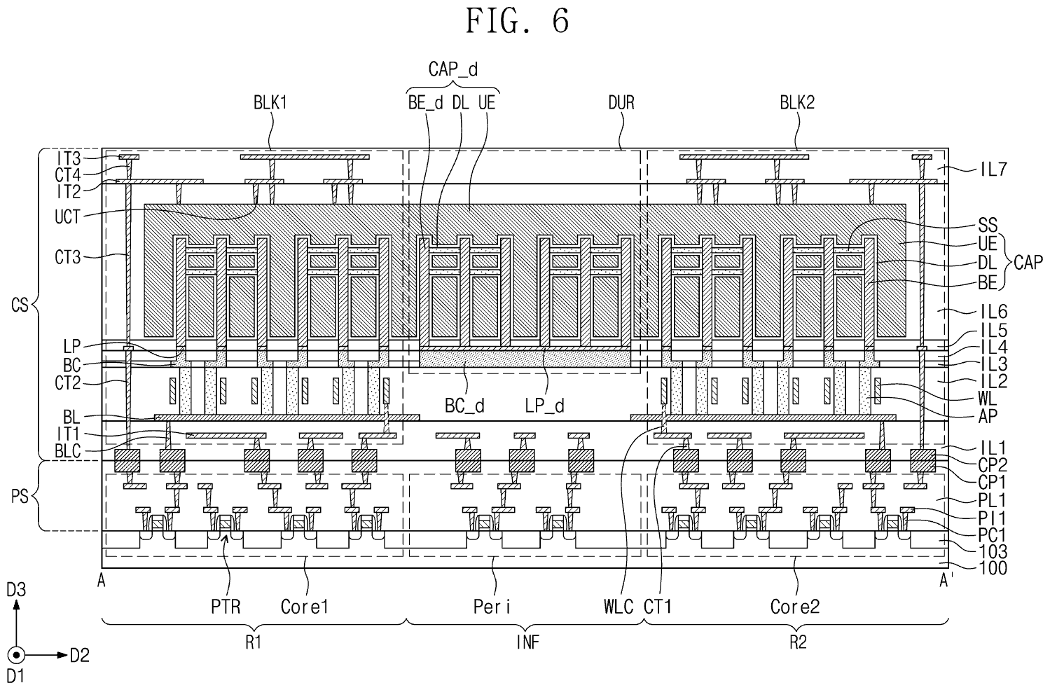

FIGS. 6, 7, and 8 illustrate cross-sectional view taken along line A-A′ of FIG. 2.

Referring to FIG. 6, in a semiconductor memory device according to the present embodiment, a peripheral structure PS and a cell structure CS may be sequentially stacked on a substrate 100. The peripheral structure PS of FIG. 6 may be substantially the same the peripheral structure PS of FIG. 3. The cell structure CS of FIG. 6 may be substantially the same as the cell structure CS of FIG. 3. The dummy landing pads LP_d may be connected into a single unitary piece. The dummy landing pad LP_d may connect bottom surfaces of the dummy bottom electrodes BE_d to each other. The dummy storage node contacts BC_d may be connected into a single unitary piece. Other configurations may be identical or similar to those discussed with reference to FIGS. 3 to 5.

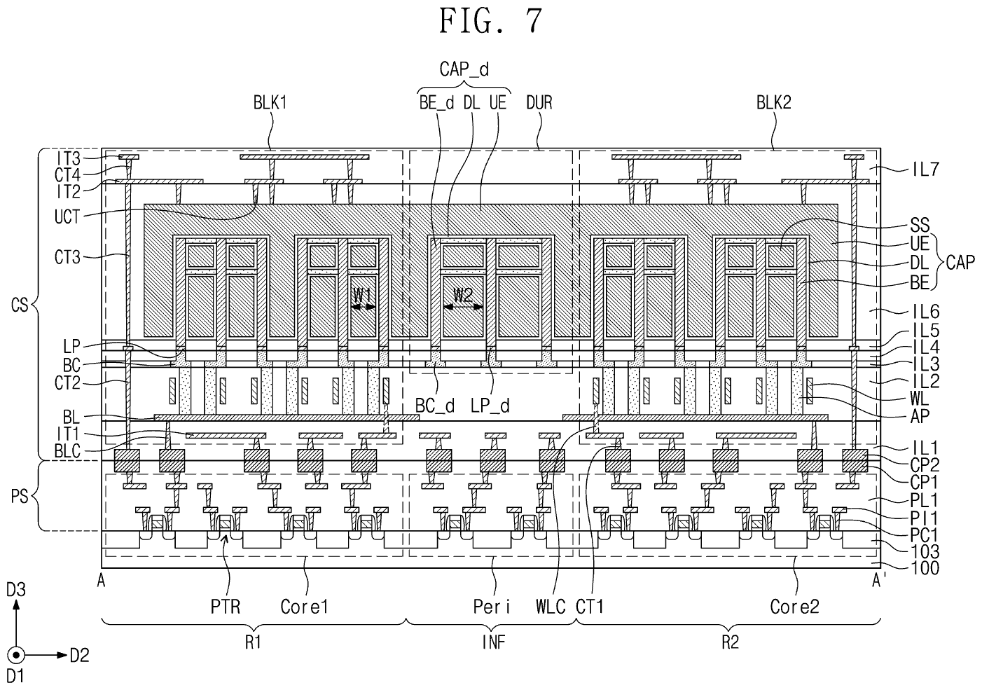

Referring to FIG. 7, in a semiconductor memory device according to the present embodiment, a peripheral structure PS and a cell structure CS may be sequentially stacked on a substrate 100. The peripheral structure PS of FIG. 7 may be substantially the same as the peripheral structure PS of FIG. 3. The cell structure CS of FIG. 7 may be substantially the same as the cell structure CS of FIG. 3. A first width W1, or an interval, between the cell bottom electrodes BE may be different from a second width W2, or an interval, between the dummy bottom electrodes BE_d. The number of the cell bottom electrodes BE on the first cell array region BLK1 or the second cell array region BLK2 may be greater than that of the dummy bottom electrodes BE_d on the boundary region INF. Other configurations may be identical or similar to those discussed with reference to FIGS. 3 to 5.

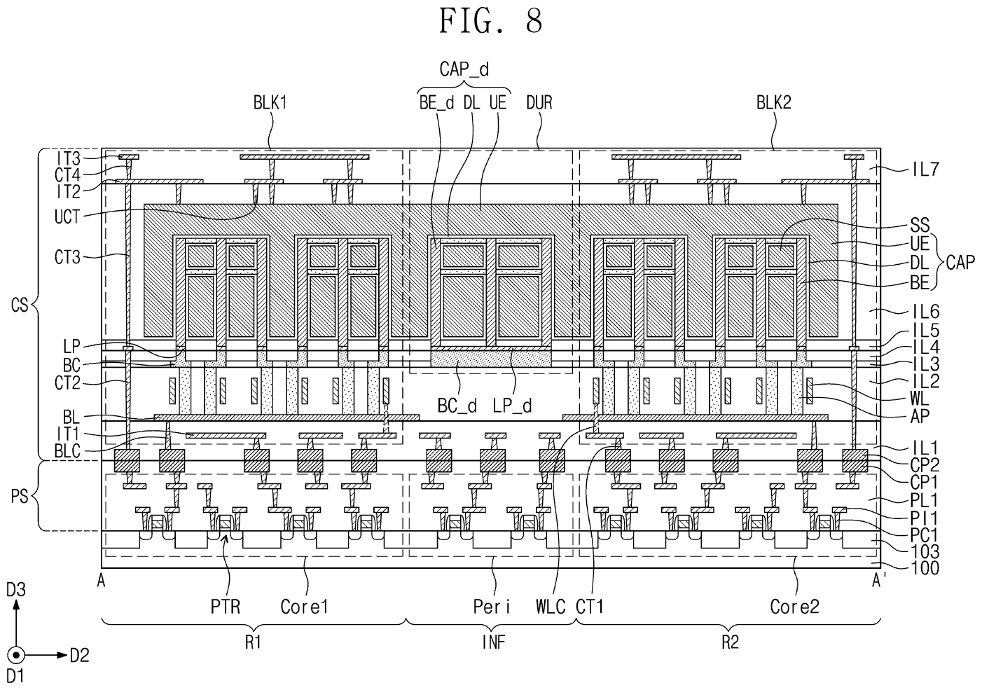

Referring to FIG. 8, in a semiconductor memory device according to the present embodiment, a peripheral structure PS and a cell structure CS may be sequentially stacked on a substrate 100. The peripheral structure PS of FIG. 8 may be substantially the same as the peripheral structure PS of FIG. 7. The cell structure CS of FIG. 8 may be substantially the same as the cell structure CS of FIG. 7. The dummy landing pads LP_d may be connected into a single unitary piece. The dummy landing pad LP_d may connect bottom surfaces of the dummy bottom electrodes BE_d to each other. The dummy storage node contacts BC_d may be connected into a single unitary piece. Other configurations may be identical or similar to those discussed with reference to FIGS. 3, 4, 5, and 7.

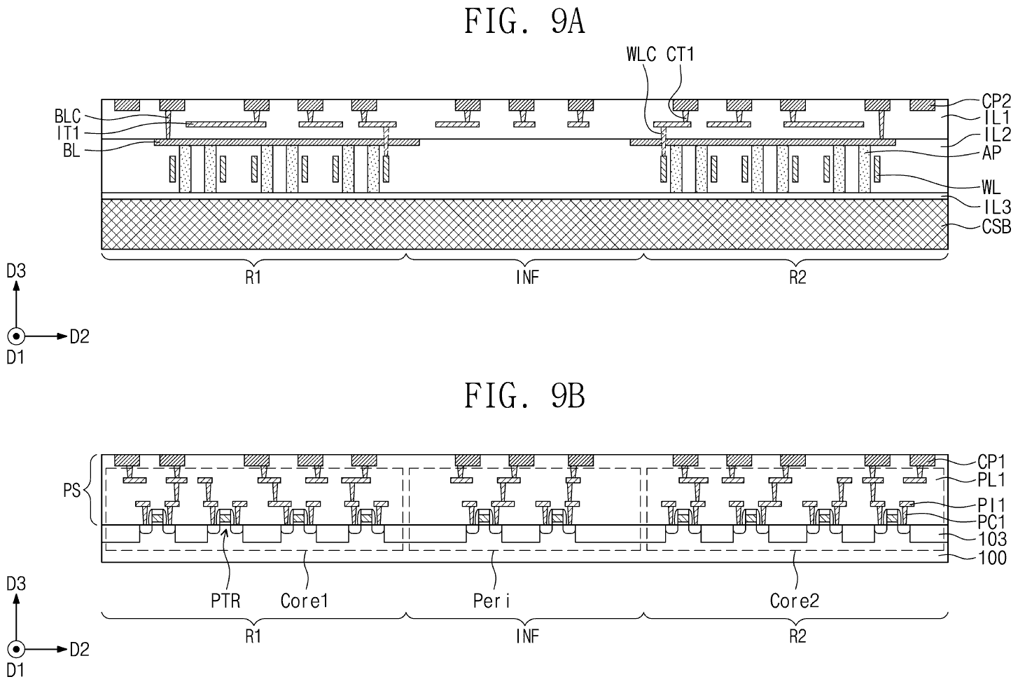

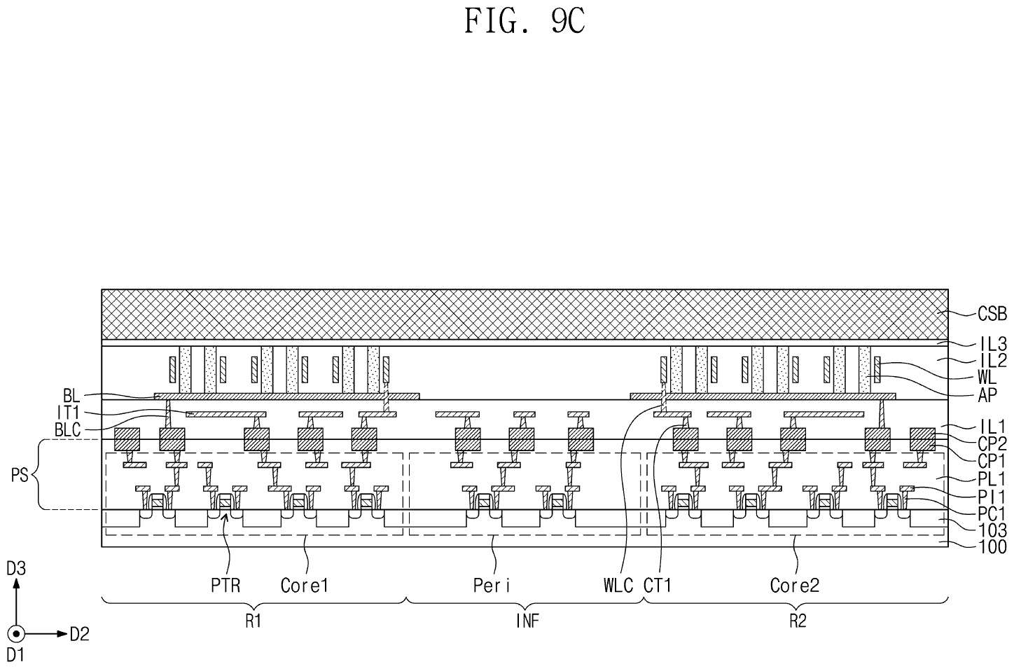

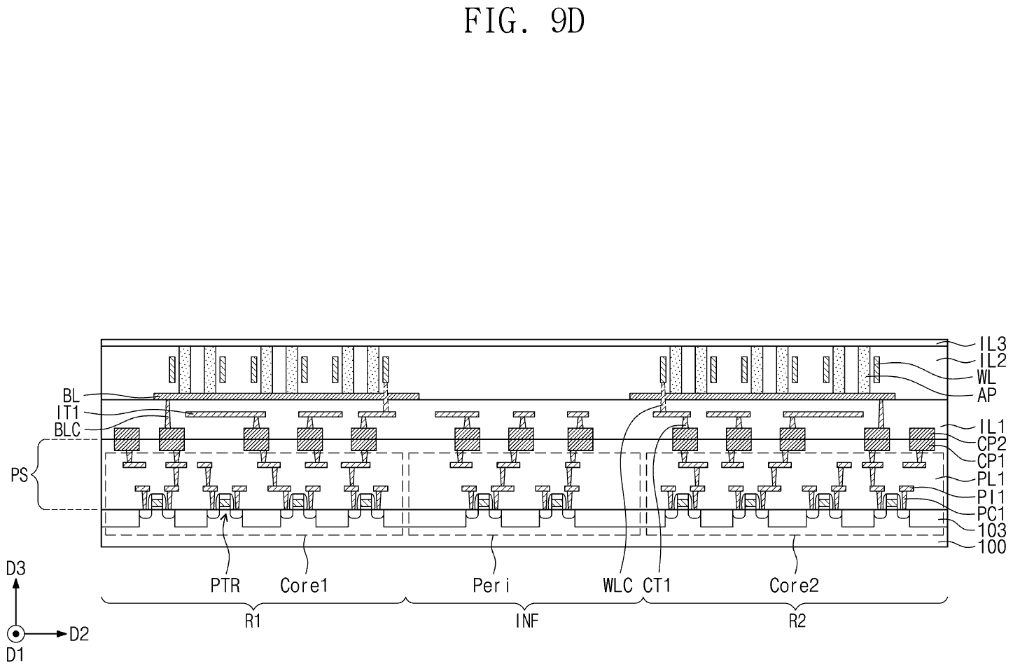

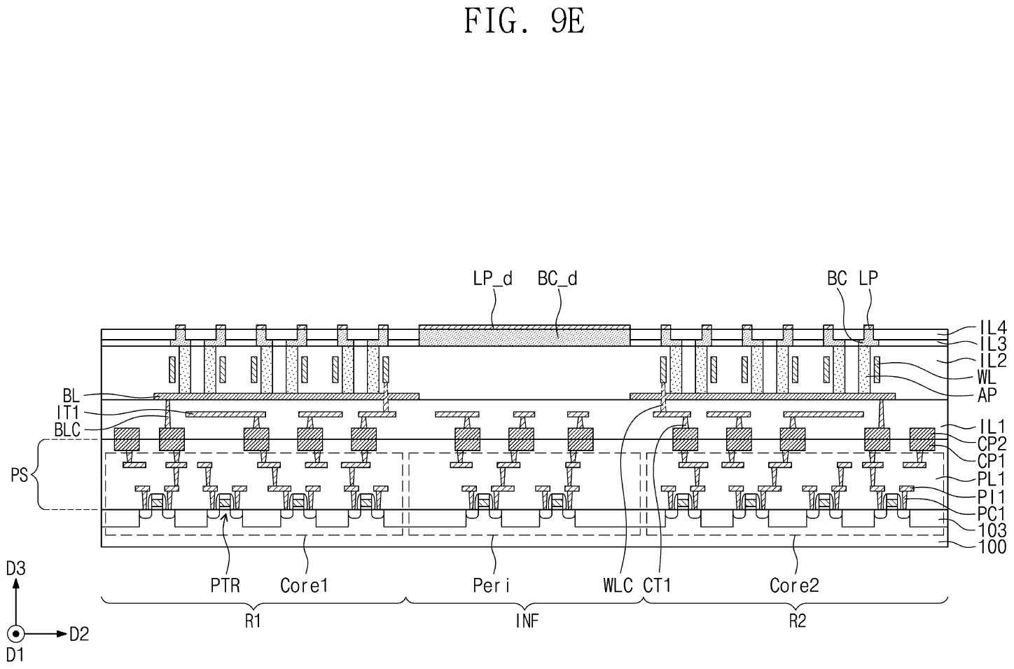

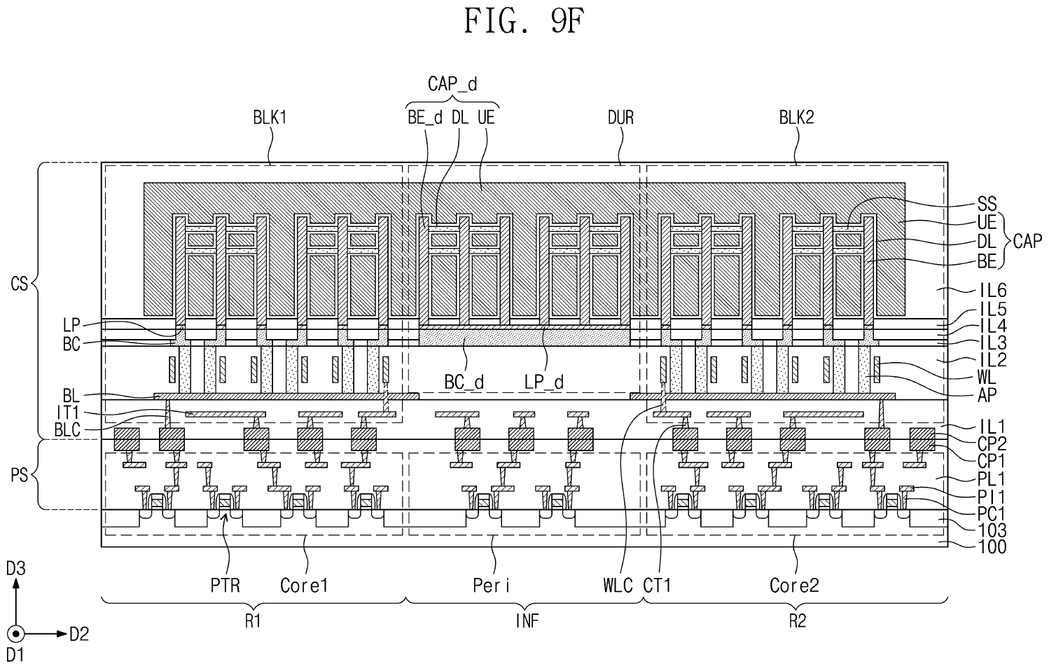

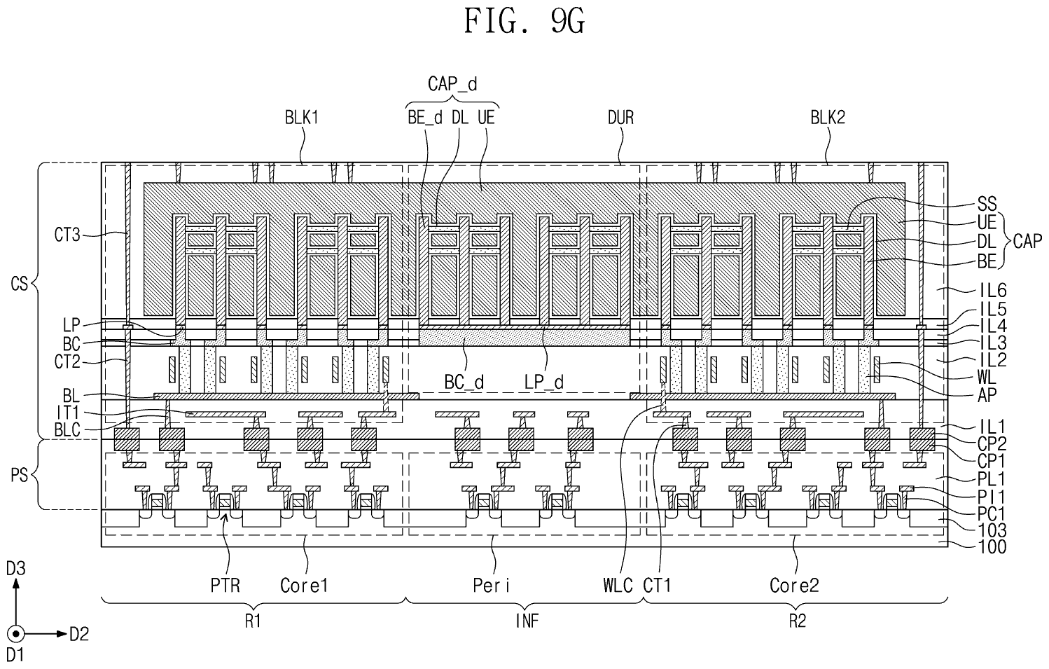

FIGS. 9A to 9G illustrate cross-sectional views showing an example method of fabricating the semiconductor memory device of FIG. 6.

Referring to FIGS. 3, 5, and 9A, a sacrificial substrate CSB may be provided. The sacrificial substrate CSB may include a first region R1, a boundary region INF, and a second region R2 that are sequentially disposed. A third cell dielectric layer IL3 may be formed on the sacrificial substrate CSB. A second cell dielectric layer IL2 may be formed on the third cell dielectric layer IL3. On the first and second regions R1 and R2, active patterns AP and word lines WL may be formed in the second cell dielectric layer IL2. On the first and second regions R1 and R2, bit lines BL may be formed on an upper portion of the second cell dielectric layer IL2. On the first and second regions R1 and R2, word-line contact plugs WLC and bit-line contact plugs BLC may be formed on the second cell dielectric layer IL2. On the first region R1, the boundary region INF, and the second region R2, first cell lines IT1, first cell contact plugs CT1, a first cell dielectric layer IL1, and second connection pads CP2 may be formed on the second cell dielectric layer IL2.

Referring to FIG. 9B, a substrate 100 may be provided. The substrate 100 may include a first region R1, a boundary region INF, and a second region R2 that are sequentially disposed. Peripheral transistors PTR, peripheral lines PI1, peripheral contact plugs PC1, and a peripheral dielectric layer PL1 may be formed on the substrate 100. Second connection pads CP2 may be formed on a top end of the peripheral dielectric layer PL1. Thus, the substrate 100 may be provided thereon on with a peripheral structure PS including a first core region Core1, a peripheral circuit region Peri, and a second core region Core2.

Referring to FIG. 9C, a structure of FIG. 9A may be overturned to reside on the peripheral structure PS of FIG. 9B, and then a thermocompression process may be performed to bond a structure of FIG. 9A to the peripheral structure PS of FIG. 9B. Thus, the peripheral dielectric layer PL1 may be in contact with the first cell dielectric layer IL1. In addition, the first connection pads CP1 may be correspondingly in contact with the second connection pads CP2.

Referring to FIG. 9D, the sacrificial substrate CSB of FIG. 9C may be separated from a surface of the third cell dielectric layer IL3. Thus, a top surface of the third cell dielectric layer IL3 may be exposed.

Referring to FIG. 9E, on the first and second regions R1 and R2, lower portions of storage node contacts BC may be formed in the third cell dielectric layer IL3, and on the boundary region INF, a lower portion of a dummy storage node contact BC_d may be formed in the third cell dielectric layer IL3. A fourth cell dielectric layer IL4 may be formed on the third cell dielectric layer IL3. On the first and second regions R1 and R2, upper portions of the storage node contacts BC may be formed in the fourth cell dielectric layer IL4, and on the boundary region INF, an upper portion of the dummy storage node contact BC_d may be formed in the fourth cell dielectric layer IL4. The dummy storage node contact BC_d may be achieved in the form of a single unitary piece.

On the first and second regions R1 and R2, landing pads LP may be formed on the fourth cell dielectric layer IL4, and on the boundary region INF, a dummy landing pad LP_d may be formed on the fourth cell dielectric layer IL4. The dummy landing pad LP_d may be achieved in the form of a single unitary piece.

Referring to FIG. 9F, a fifth cell dielectric layer IL5 may be formed to cover the fourth cell dielectric layer IL4. On the first and second regions R1 and R2, cell bottom electrodes BE may be formed on the fifth cell dielectric layer IL5, and on the boundary region INF, dummy bottom electrodes BE_d may be formed on the fifth cell dielectric layer IL5. A dielectric layer DL and a top electrode UE may be sequentially conformally stacked on the cell bottom electrodes BE and the dummy bottom electrodes BE_d to form capacitors CAP and dummy capacitors CAP_d.

As the dummy bottom electrodes BE_d are disposed on the boundary region INF between the cell bottom electrodes BE, it may be easy to form the top electrode UE on the first and second regions R1 and R2 and on the boundary region INF.

In the present inventive concepts, the top electrode UE may not be cut between the boundary region INF and the first and second regions R1 and R2. Therefore, since no misalignment margin is required for cutting the top electrode UE, there may be a reduction in interval between the first and second regions R1 and R2.

A sixth cell dielectric layer IL6 may be formed to cover the capacitors CAP and the dummy capacitors CAP_d. The sixth cell dielectric layer IL6 may undergo a chemical mechanical polishing (CMP) process or an etch-back process. In this step, as the top electrode UE is disposed even on the boundary region INF, and as the dummy bottom electrodes BE_d allow the top electrode UE to have a relatively flat top surface, no dishing phenomenon may occur when the CMP process is performed on the sixth cell dielectric layer IL6.

In addition, the occurrence of void may be prevented between the top electrode UE and the sixth cell dielectric layer IL6. The top electrode UE covering the dummy bottom electrodes BE_d may facilitate the planarization of the sixth cell dielectric layer IL6. Thus, process failure may be prevented to provide a semiconductor memory device with improved structural stability. Therefore, a first cell array region BLK1, a dummy region DUR, and a second cell array region BLK2 may be formed in the cell structure CS.

Referring to FIG. 9G, there may be formed upper electrode contact plugs UCT, second cell contact plugs CT2, and third cell contact plugs CT3 that penetrate the sixth cell dielectric layer IL6.

Subsequently, referring to FIG. 6, second cell lines IT2, fourth cell contact plugs CT4, and a seventh cell dielectric layer IL7 may be formed to manufacture a cell structure CS. Through aforementioned processes, a semiconductor memory device may be fabricated as shown in FIG. 6.

In a semiconductor memory device according to the present inventive concepts, dummy bottom electrodes may be disposed on a boundary region (or a peripheral region) between cell bottom electrodes on cell array regions. A top electrode may cover all of the cell bottom electrodes and dummy bottom electrodes, and the dummy bottom electrodes may facilitate the formation of the top electrode. In addition, the occurrence of void may be prevented between the top electrode and its overlying cell dielectric layer, and a cell dielectric layer may be easily planarized.

Moreover, in the present inventive concepts, the top electrode may not be cut on an edge between the boundary region and the cell array regions, and therefore no alignment margin may be required for cutting the top electrode. There may thus be a reduction in interval between the cell array regions. Accordingly, a semiconductor device may decrease in horizontal size and signal delivery distance. Further, a delamination may be prevented between the top electrode and the cell dielectric layer.

Although some example embodiments of inventive concepts have been discussed with reference to accompanying figures, it will be understood that various changes in form and details may be made therein without departing from the spirit and scope of inventive concepts. It will be apparent to those skilled in the art that various substitution, modifications, and changes may be thereto without departing from the scope and spirit of the present inventive concepts.

What is claimed is:

1. A semiconductor memory device, comprising:
a substrate that includes a first region, a boundary region, and a second region that are linearly disposed in a first direction; and
a peripheral structure and a cell structure that are sequentially stacked on the substrate,
wherein the cell structure includes:
a plurality of cell bottom electrodes on the first region and the second region;
a plurality of dummy bottom electrodes on the boundary region;
a top electrode that covers the cell bottom electrodes and the dummy bottom electrodes; and
a dielectric layer between the top electrode and the cell bottom electrodes and between the top electrode and the dummy bottom electrodes.

2. The device of claim 1, wherein the cell structure includes:
a plurality of active patterns between the cell bottom electrodes and the substrate and two-dimensionally arranged along a top surface of the substrate;
a plurality of bit lines between the active patterns and the substrate, the bit lines extending in the first direction; and
a plurality of word lines adjacent to sidewalls of the active patterns, the word lines extending in a second direction that intersects the first direction.

3. The device of claim 2, wherein the cell structure further includes:
a plurality of storage node contacts correspondingly on the active patterns; and
a plurality of landing pads correspondingly between the storage node contacts and the cell bottom electrodes.

4. The device of claim 1, wherein the cell structure further includes:
a plurality of dummy storage node contacts correspondingly beneath the dummy bottom electrodes; and
a plurality of dummy landing pads correspondingly between the dummy bottom electrodes and the dummy storage node contacts.

5. The device of claim 4,
wherein the plurality of dummy storage node contacts are connected into a single unitary piece, and
wherein the plurality of dummy landing pads are connected into a single unitary piece.

6. The device of claim 1, wherein the peripheral structure includes:
a first core circuit part on the first region;
a second core circuit part on the second region; and
a peripheral circuit part on the boundary region.

7. The device of claim 1, wherein an interval between the dummy bottom electrodes is the same as an interval between the cell bottom electrodes.

8. The device of claim 1,
wherein the peripheral structure includes a plurality of first connection pads on a top surface of the peripheral structure,
wherein the cell structure includes a plurality of second connection pads on a bottom surface of the cell structure, and
wherein the first connection pads are in contact with the second connection pad.

9. The device of claim 1, wherein a top surface of the top electrode has a recess on the boundary region.

10. The device of claim 9,
wherein the cell structure further includes a cell dielectric layer that covers the top electrode, and
wherein, on the recess, the cell dielectric layer has a flat top surface.

11. A semiconductor memory device, comprising:
a substrate that includes a first region, a boundary region, and a second region that are linearly disposed in a first direction; and
a peripheral structure and a cell structure that are sequentially stacked on the substrate,
wherein the peripheral structure includes:
a plurality of peripheral transistors on the substrate;
a first peripheral dielectric layer that covers the substrate; and
a plurality of first peripheral lines in the first peripheral dielectric layer,
wherein the cell structure includes:
a first cell dielectric layer and a second cell dielectric layer that sequentially cover the peripheral structure;
a plurality of first cell lines in the first cell dielectric layer;
a plurality of active patterns, a plurality of word lines, and a plurality of bit lines in the second cell dielectric layer;
a plurality of cell bottom electrodes on the second cell dielectric layer on the first region and the second region;
a plurality of dummy bottom electrodes on the second cell dielectric layer on the boundary region;
a top electrode that covers the cell bottom electrodes and the dummy bottom electrodes; and
a dielectric layer between the top electrode and the cell bottom electrodes and between the top electrode and the dummy bottom electrodes,
wherein the bit lines connect bottom surfaces of the active patterns to each other and extend in the first direction,
wherein the word lines are adjacent to lateral surfaces of the active patterns and extend in a second direction that intersects the first direction, and
wherein an interval between the dummy bottom electrodes is different from an interval between the cell bottom electrodes.

12. The device of claim 11, wherein the cell structure further includes:
a plurality of storage node contacts correspondingly on the active patterns; and
a plurality of landing pads correspondingly between the storage node contacts and the cell bottom electrodes.

13. The device of claim 12, wherein the cell structure further includes:
a plurality of dummy storage node contacts correspondingly beneath the dummy bottom electrodes; and
a plurality of dummy landing pads correspondingly between the dummy bottom electrodes and the dummy storage node contacts.

14. The device of claim 13,
wherein the plurality of dummy storage node contacts are connected into a single unitary piece, and
wherein the plurality of dummy landing pads are connected into a single unitary piece.

15. The device of claim 11, wherein a top surface of the top electrode has a recess on the boundary region.

16. A semiconductor memory device, comprising:
a substrate that includes a first region, a boundary region, and a second region that are linearly disposed in a first direction; and
a peripheral structure and a cell structure that are sequentially stacked on the substrate,
wherein the cell structure includes:
a plurality of cell bottom electrodes on the first region and the second region;
a plurality of dummy bottom electrodes on the boundary region;
a top electrode that covers the cell bottom electrodes and the dummy bottom electrodes;
a dummy landing pad that connects bottom surfaces of the dummy bottom electrodes to each other; and
a dummy storage node contact beneath the dummy landing pad.

17. The device of claim 16, wherein the cell structure further includes:
a plurality of active patterns between the cell bottom electrodes and the substrate and two-dimensionally arranged along a top surface of the substrate;
a plurality of bit lines between the active patterns and the substrate, the bit lines extending in the first direction; and
a plurality of word lines adjacent to sidewalls of the active patterns, the word lines extending in a second direction that intersects the first direction.

18. The device of claim 16, wherein an interval between the dummy bottom electrodes is different from an interval between the cell bottom electrodes.

19. The device of claim 16, wherein the peripheral structure includes:
a first core circuit part on the first region;
a second core circuit part on the second region; and
a peripheral circuit part on the boundary region.

20. The device of claim 16, wherein a top surface of the top electrode has a recess on the boundary region.
